(19) United States
(12) Patent Application Publication
(10) Pub. No.: US 2008/0302410 A1
(43) Pub. Date: Dec. 11, 2008

(54) SOLAR CELL MODULE CONNECTOR AND METHOD OF PRODUCING SOLAR CELL MODULE PANEL

(75) Inventor: Masahiro Aoyama, Osaka-shi (JP)

Correspondence Address: DUANE MORRIS LLP - Philadelphia;IP DEPARTMENT, 30 SOUTH 17TH STREET, PHILADELPHIA, PA, 19103-4196, US

(73) Assignee: Sansha Electric Manufacturing Company, Limited, Osaka-shi (JP)

(21) Appl. No.: 12/169,839

(22) Filed: Jul. 9, 2008

Related U.S. Application Data
(62) Division of application No. 11/125,951, filed on May 10, 2005.

(30) Foreign Application Priority Data
May 18, 2004 (JP) 2004-147793

(51) Int. Cl. H01L 31/042

(52) U.S. Cl. 136/251

(57) ABSTRACT

A solar cell module connector includes an insulating box (2). The insulating box includes a solar cell module lead line connection zone (8) and an output cable connection zone (12) disposed on opposite sides of an diode zone (10), with partitions (4, 6) disposed therebetween, respectively. Heat sinks (14) are disposed in the diode zone, with their first ends located in said solar cell module lead line connection zone and with their second ends located in said output cable connection zone. Connection terminals (26) are connected to the respective ones of the first ends of the heat sinks and extend through the partition (4) into the solar cell module lead line connection zone. Connection terminals (30) are connected to the second ends of the heat sinks disposed at the opposite, first and second outermost locations and extend through the partition (6) into the output cable connection zone. Anodes of chip-type diodes (18) are connected to the respective heat sinks expect one of the two outermost heat sinks, with their cathodes connected to the respective ones of the heat sinks adjacent on the first outermost location side.

### CROSS-REFERENCE TO RELATED APPLICATION

This application is a divisional patent application of, and claims priority to, U.S. patent application Ser. No. 11/125,951, filed May 10, 2005, the entirety of which is hereby incorporated by reference herein.

### FIELD OF THE INVENTION

This invention relates to a connector for connecting solar cell modules and a method of producing a solar cell module panel with such connector.

### BACKGROUND OF THE INVENTION

Sometimes, in order to derive a desired magnitude of voltage, a plurality of solar cell modules are connected in series on the spot by means of solar cell module connectors. Also, bypass diodes may sometimes be connected to the respective modules in the connector. Various techniques have been developed to make such connectors thin and still electrically reliable. One example is disclosed in Japanese Patent Application Publication No. HEI 5-343724 A.

According to the technique disclosed in this Japanese publication, a relay terminal carrying board is disposed in a terminal box. Two electrically conductive relay terminal connecting portions are formed, being spaced from each other, on the relay terminal carrying board. The anode of a pellet-shaped bypass diode is soldered to one of the conductive relay terminal portions, with the cathode connected by means of a lead line to the other conductive relay terminal connecting portion. Two output lead lines are connected to the respective relay terminal connecting portions, through which the bypass diode is connected to a solar cell module. Two relay frames are connected to the respective relay terminal connecting portions, through which the output of the solar cell module is derived.

Usually, such terminal box is used outdoors with a solar cell module under severe environmental conditions. It is, therefore, necessary that the diodes be mounted firmly. However, the diodes used in the Japanese publication are in the form of a mechanically weak, thin semiconductor pellet and, therefore, are easily damaged when subjected to vibrations and impact.

An object of the present invention is to provide a solar cell module connector which can be used reliably under severe environmental conditions. Another object of the present invention is to provide a method of producing a solar cell module free of causes which would induce performance unstableness of the solar cell module.

### SUMMARY OF THE INVENTION

According to one aspect of the invention, a method of producing a solar cell module panel with a connector is provided. First, an insulating box is formed. The insulating box has a diode zone, on opposite sides of which a solar cell module lead line connection zone and an output cable connection zone are formed respectively, with respective partitions disposed between the diode zone and the solar cell module lead line connection zone and between the diode zone and the output cable connection zone. A series combination of a plurality of diodes is disposed in the diode zone. A plurality of lead line connection terminals are extended to the solar cell module lead line connection zone from the two opposite ends of the diode series combination and the junctions of the respective ones of the series connected diodes. Also, cable connection terminals are extended from the opposite ends of the diode series combination to the output cable connection zone. The diode zone is filled with an insulating material. This completes an interim assembly. The interim assembly is tested for its characteristics. The interim assembly is mounted on a rear surface of a solar cell module panel. In this manner, an interim assembly found to have proper characteristics in the test is mounted on the panel. The lead lines of the respective solar cell modules on the solar cell module panel are connected to the lead line connection terminals, and output cables are connected to the cable connection terminals.

A connector according to another aspect of the present invention has an insulating box. The insulating box has a diode zone, on opposite sides of which disposed are a solar cell module lead line connection zone and an output cable connection zone, with respective partitions disposed between the diode zone and the respective ones of the solar cell module lead line connection and output cable connection zones. For example, the solar cell module lead line connection zone is formed on one side of the diode zone with a first one of the partitions disposed between them, while the output cable connection zone is formed on the other side of the diode zone with a second one of the partitions disposed between them. A plurality of heat sinks are disposed in a row in the diode zone, being spaced from each other. A first end of each heat sink is located nearer to the solar cell module lead line connection zone, and a second end of each heat sink is located nearer to the output cable connection zone. A lead line connection terminal is connected to the first end of each heat sink and extends through the first partition into the solar cell module lead line connection zone. A cable connection terminal is connected to the second end of each of first and second heat sinks at opposite ends of the row of the heat sinks and extends through the second partition into the output cable connection zone. An anode of a diode is connected to each of the heat sinks except the first heat sink, and its cathode is connected to the adjacent heat sink on the first heat sink side of that diode. At least part of the depth of the diode zone is filled with an insulating material in such a manner that the diodes can be completely covered with the insulating material. Similarly, the solar cell module lead line connection zone and the output cable connection zone may be at least partly filled with an insulating material. The diodes may be chip-type diodes or chip-type diodes molded in a resin.

Because the chip-type diodes are covered with an insulating material, the characteristics of the diodes hardly degrade even under severe environmental conditions.

Each heat sink may be provided with a socket with which the cathode of the associated diode may be connected. This arrangement makes it easier to connect the cathodes to the heat sinks.

A solar cell module connector according to another aspect includes an insulating box as the above-described connector according to the first aspect. A diode module is disposed in a diode zone of the insulating box. The diode module includes therein a series combination of a plurality of diodes. The diode module further includes a heat sink for use in common to all of the diodes. The heat sink is on the bottom of the diode zone. Terminal portions through which connections to the opposite two ends of the series combination of diodes and to the nodes between adjacent ones of the diodes are formed on the top surface of the diode module. A first connection terminal extends from each end of the series combination of the diodes through the first and second partitions to the solar cell module lead line connection zone and to the output cable connection zone, respectively. Each of the first connection terminals may be a single member, or may be provided by separate members extending respectively into the solar cell module lead line connection zone and the output cable connection zone. A second connection terminal extends from each of the terminal portions connected to the nodes of adjacent diodes to the solar cell module lead line connection zone through the first partition. Since the diodes are encapsulated into a diode module, the characteristics of the diodes do not largely vary with temperature and/or humidity changes.

According to still another embodiment of the invention, a solar cell module connector includes an insulating box. The insulating box includes a diode zone with an opening on one side thereof, and a partition closing the opening. A plurality of heat sinks are arranged, being spaced from each other, in the diode zone, and a diode is disposed on each of the heat sinks. An insulating material is placed in the diode zone so as to cover the respective diodes. Each diode includes an anode lead and a cathode lead extending through the partition. A plurality of connection means are provided in the partition to connect the diodes in series, by connecting the anode of one diode to the cathode of another diode. One end of each connection means is used as a solar cell module lead line connection terminal. The other ends of the connecting means located at the respective ends of the series combination of the diodes are used as the output cable connection terminals. Since the diodes are encapsulated in the insulating material, the characteristics of the diodes hardly vary even when the environmental temperature and humidity change.

### BRIEF DESCRIPTION OF THE DRAWINGS

FIG. 1A is a front elevational view of a connector according to a first embodiment of the present invention, FIG. 1B is a cross-sectional view along a line 1B-1B in FIG. 1A, FIG. 1C is a cross-sectional view along a line 1C-1C in FIG. 1A, and FIG. 1D is a cross-sectional view along a line 1D-1D in FIG. 1.

FIG. 2 is a cross-sectional view, equivalent to FIG. 1B, showing a modification of the connector shown in FIGS. 1A-1B.

FIG. 3A is a front elevational view of a connector according to a second embodiment of the present invention, and FIG. 3B is a cross-sectional view along a line 3B-3B in FIG. 3A.

FIG. 4A is a front elevational view of a connector according to a third embodiment of the present invention, FIG. 4B is a cross-sectional view along a line 4B-4B in FIG. 4A, and FIG. 4C is a cross-sectional view along a line 4C-4C in FIG. 4A.

FIG. 5A is a front elevational view of a connector according to a fourth embodiment of the present invention, FIG. 5B is a cross-sectional view along a line 5B-5B in FIG. 5A, and FIG. 5C is a cross-sectional view along a line 5C-5C in FIG. 5A.

FIG. 6A is a front elevational view of a connector according to a fifth embodiment of the present invention, and FIG. 6B is a cross-sectional view along a line 6B-6B in FIG. 6A.

FIG. 7 is an exploded, perspective view of a connector according to a sixth embodiment of the present invention.

### DESCRIPTION OF EMBODIMENTS

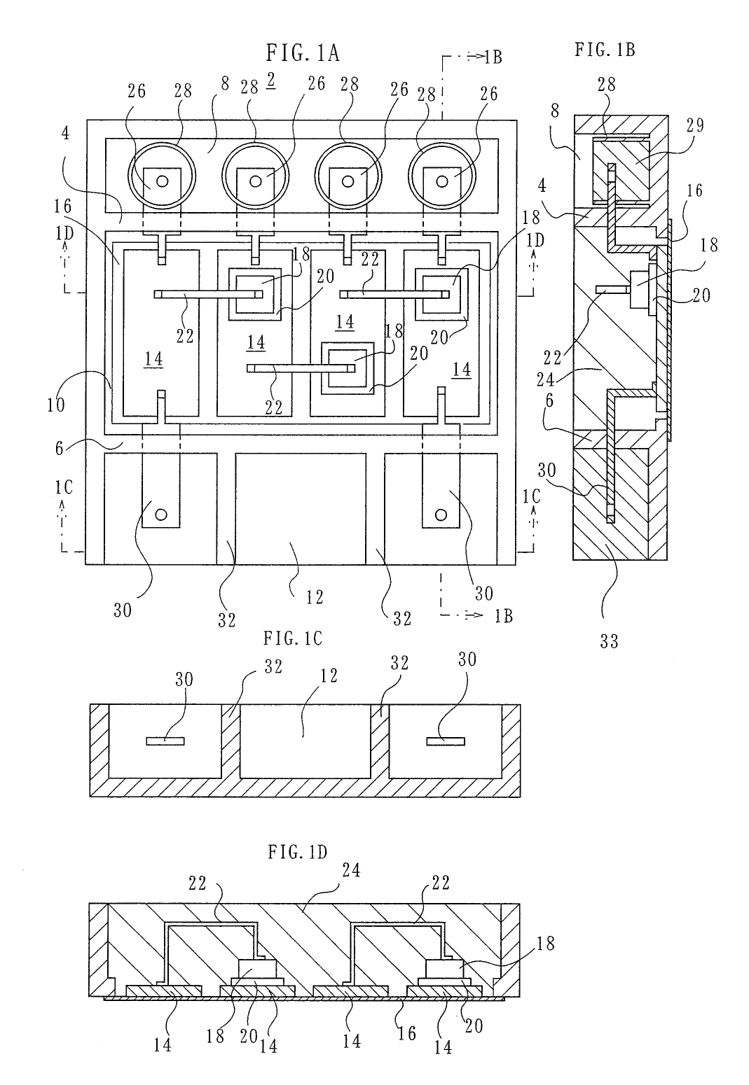

A solar cell module connector according to a first embodiment of the present invention has an insulating box 2 as shown in FIGS. 1A through 1D. The insulating box 2 may be formed of an insulating material, e.g. an epoxy resin. Two spaced-apart partitions 4 and 6 divide the insulating box 2 into three zones, namely, a solar cell module lead line terminal zone 8, a diode heat sink zone 10, and an output cable terminal zone 12.

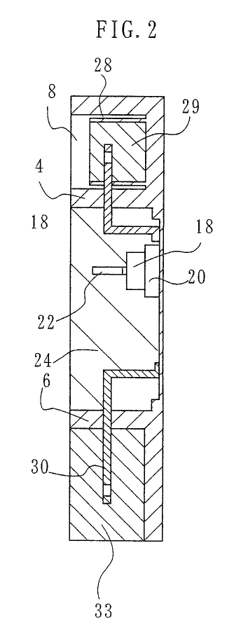

Plural, four, for example, heat sinks 14 are arranged in a row in the diode heat sink zone 10, being spaced from and in parallel with each other. Each of the heat sinks 14 may be a rectangular steel plate having a thickness of, for example, 3 mm. One end of each heat sink 14 is located nearer to the solar cell module lead line terminal zone 8, while the other, opposite end of each heat sink 14 is located nearer to the output cable connection terminal zone 12. The bottom of the diode heat sink zone 10 is partly or entirely removed to form an opening, and a heat-conductive insulating sheet 16 having good heat conductivity is bonded to close the opening, as shown in FIGS. 1B and 1C. The bottom surfaces of the heat sinks 14 are bonded to the upper surface of the heat-conductive sheet 16. In place of using the heat-conductive sheet 16, those portions of the bottom wall of the diode heat sink zone 10 where the respective heat sinks 14 are mounted and the surrounding portions may be thinned relative to the remaining portion as shown in FIG. 2.

On the top surfaces of the heat sinks 14, except the heat sink 14 at one end of the row (e.g. the leftmost one in the example shown in FIG. 1A), the anodes of diodes, e.g. diode chips 18, are mounted by means of solder 20, one for each heat sink 14. Each diode chip 18 has a cathode formed to oppose the anode, which is soldered through a lead 22 to the heat sink 14 adjacent on one side, on the left side in the example shown in FIG. 1A, as is shown also in FIG. 1D. This connection provides a series combination of the like poled diode chips 18.

The entirety of the diode heat sink zone 10 is filled with an insulating material 24, e.g. an epoxy resin, to cover the diode chips 18 and the heat sinks 14. The insulating material 24 is not shown in FIGS. 1A and 1C in order to avoid complexity of illustration. Because the diode chips 18 are protected by the insulating material 24, they can endure temperature and humidity changes and, therefore, can maintain reliability.

A first end of a solar cell module lead line connection terminal 26 is soldered to the end of each diode heat sink 14 on the side nearer to the solar cell module lead line terminal zone 8, and extends through the partition 4 into the solar cell module lead line terminal zone 8. The terminals 26 are connected to the opposing two ends of the series combination of the diode chips 18 and to the junctions of adjacent ones of the diode chips 18. Lead lines of the respective solar cell modules are adapted to be connected to the opposite, second ends of the terminals 26 in the zone 8. For example, two lead lines of one solar cell module are connected to the leftmost terminal 26 in FIG. 1A and to the second leftmost terminal 26 adjacent in the right to the leftmost terminal 26, two lead lines of another solar cell module are connected to the second leftmost terminal 26 and to the third terminal 26 adjacent in the right to the second leftmost terminal 26, and two lead lines of a still another solar cell module are connected to the third terminal 26 and to the fourth terminal 26 adjacent in the right to the third terminal 26. By this connection, a plurality, three in the example being described, of solar cell modules are connected in series through the diode chips 18. A cylindrical rib 28 is formed around the second end of each terminal 26. Once the leads of the solar cell modules are connected to the terminals 26, an insulating material 29, e.g. an epoxy resin, is placed into the interior of each cylinder 28 to encapsulate the terminals 26, which makes the terminals 26 endurable against temperature and humidity changes. The insulating material 29 is shown only in FIG. 1B in order to avoid complexity of illustration.

An output cable connection terminal 30 is soldered to each of the outermost heat sinks 14 at one end nearer to the output cable terminal zone 12. These two connection terminals 30 are connected to the respective ends of the series combination of the diode chips 18, and extend through the partition 6 into the output cable terminal zone 12. An output cable is adapted to be connected to the end of each output cable connection terminal 30, whereby an output voltage can be derived from the two ends of the series combination of the three solar cell modules. Two spaced-apart ribs 32 are provided in the output cable zone 12, and an insulating material 33, e.g. an epoxy resin, is placed in two spaces defined by the two ribs 33 and the two respective outer walls of the output cable zone 12 to embed the output cable connection terminals 30 therein so that the terminals 30 can endure temperature and humidity variations. It should be noted that the insulator 33 is shown only in FIG. 1B in order to simplify the drawings.

The terminals 26 and 30 are connected not directly to the diode chips 18, but are connected to the diode chips 18 via the heat sinks 14. Accordingly, when vibrations, for example, are given to the terminals 26 and 30, such vibrations do not transmitted directly to the diode chips 18. In other words, the diode chips 18 can have increased resistance against vibrations.

Although not shown in the drawings, the solar cell module lead line terminal zone 8 and the output cable terminal zone 12 may be provided with through-holes extending through the bottoms thereof, for leading, therethrough, the lead lines and the output cables into the respective zones 8 and 12 from outside the insulating box 2.

When producing the connector arranged as described above, the insulating box 2 is first prepared, then, the heat sinks 14 are mount in the diode heat sink zone 10, and, then, the connection terminals 26 and 30 are mounted to the corresponding heat sinks 14. After that, the diode chips 18 are mounted on the associated heat sinks 14, and the lead lines 22 are connected. After that, the diode heat sink zone 10 is filled with the insulating material 24, to thereby complete a first-stage interim assembly. Then, tests for characteristics of the first-stage interim assembly are carried out. If the test results are acceptable, the diode chips 18 of the first-stage interim assembly can endure long-term temperature and humidity variations.

The above-described first-stage interim assembly is mounted on the rear surface of a solar cell module panel on which the solar cell modules are mounted. The rear surface is the surface opposite to the surface on which solar rays are incident. Specifically, the first-stage interim assembly is mounted on the solar cell module panel, with the heat-conductive insulating sheet 16 contacting the rear surface of the panel. This makes the solar cell module panel function as the heat sink for the diode chips 18. Then, lead lines of the respective solar cell modules are connected to the respective connection terminals 26 to thereby complete a second-stage interim assembly. Then, the second-stage interim assembly is subjected to characteristic tests, and, if the test results are acceptable, the step for filling with the insulating material 29 is performed. If the test results are not acceptable, appropriate adjustments are made to make the assembly acceptable.

Next, the output cables are connected to the connection terminals 30 of the second-stage interim assembly to form a third-stage interim assembly. The third-stage interim assembly is then subjected to characteristic tests, and, if the test results are acceptable, the insulating material 33 is placed. If the test results are not acceptable, appropriate adjustments are made to make the assembly acceptable.

As characteristics tests are carried out for each interim stage of the assembly, the number of repetitions of manufacturing steps can be reduced relative to a case in which characteristic tests are carried out for assemblies in the final stage.

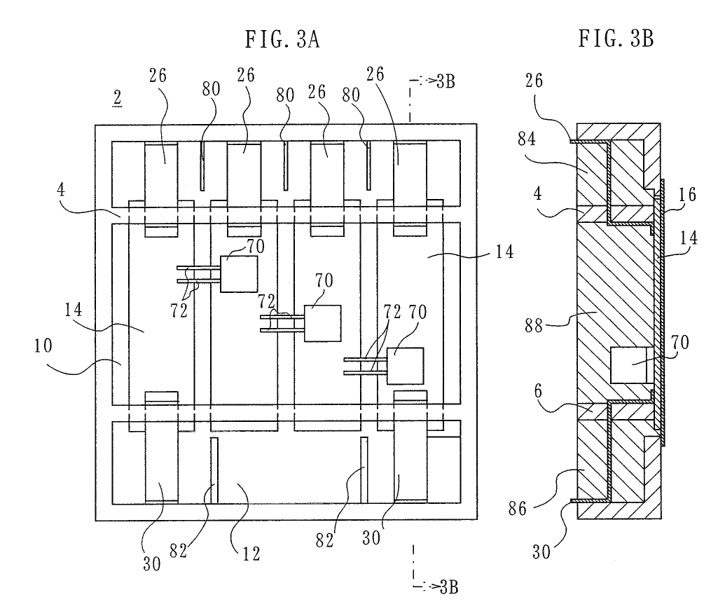

A connector according to a second embodiment is shown in FIGS. 3A and 3B. This connector employs molded diodes 70 in place of the diode chips 18 used in the connector according to the first embodiment. Each molded diode 70 includes a diode chip embedded in an insulating casing, with an anode of the diode chip connected to a metal plate disposed at the bottom of the casing. The metal plate functions as an anode electrode of the diode chip. The cathode of the diode chip is connected to two cathode electrode pins 72 within the casing, which cathode electrode pins 72 extend in parallel outward through the wall of the casing. Each molded diode 70 is disposed on a heat sink 14, and the cathode electrode pins 72 of each molded diode 70 are soldered to the heat sink 14 located adjacent on one side, i.e. the left side in the illustrated embodiment, to the heat sink 14 on which that molded diode 70 is disposed. The arrangements of the remaining portions are similar to the connector according to the first embodiment, and, therefore, the same reference numerals are attached to the same or similar components or functions, without making any additional descriptions about them. The connector according to the second embodiment is manufactured in a manner similar to the first embodiment.

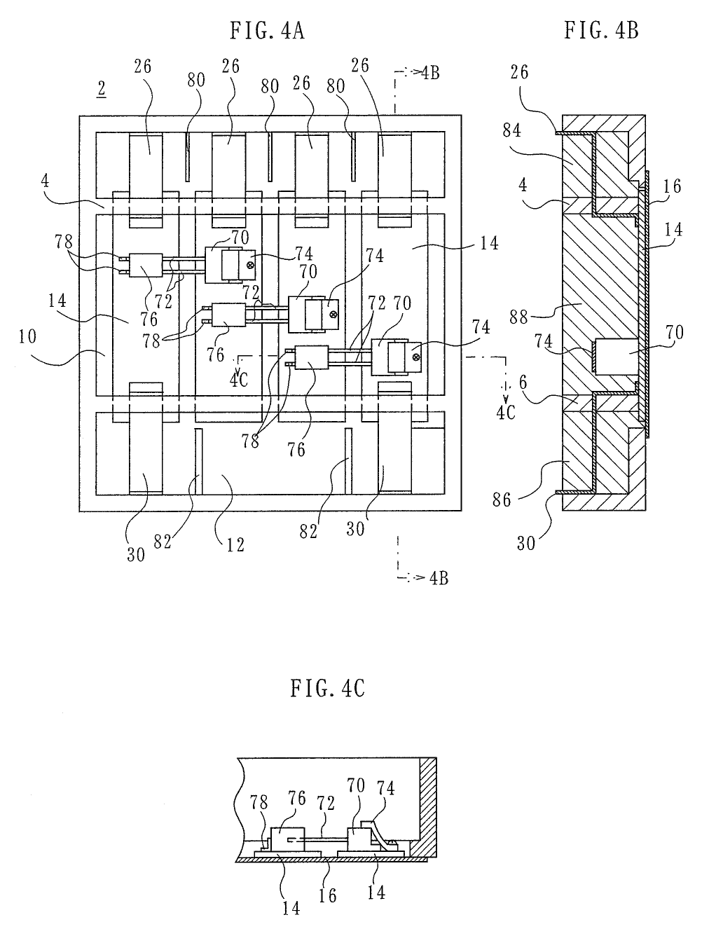

A connector according to a third embodiment of the present invention is shown in FIGS. 4A, 4B and 4C. According to the third embodiment, the molded diodes 70 of the connector according to the second embodiment have their anode electrodes secured to and in contact with the associated heat sinks 14 with fastening members 74, which press down the molded diodes 70 down against the heat sinks 14. The cathode electrode pins 72 are inserted into associated sockets 76 secured onto the different heat sinks 14 located adjacent on one side, i.e. the left side in the illustrated embodiment, to the heat sink 14 on which that molded diode 70 is disposed. The respective sockets 76 have their pins 78 soldered to the associated heat sinks 14. The arrangements of the remaining portions are similar to the connector according to the second embodiment, and, therefore, the same reference numerals are attached to the same or similar components or functions, and their detailed descriptions are not made.

According to this embodiment, since the molded diodes 70 have their anodes electrically connected to and mounted on the heat sinks 14 by means of the fastening members 74 and have their cathodes connected by means of the sockets 76, the steps for soldering the diodes can be eliminated. Thus, the working for electrical connections and mounting of the diodes becomes easier and simpler.

Because the respective end portions of each heat sink 14 extend beyond the partitions 4 and 6 into the solar cell module lead line terminal zone 8 and the output cable terminal zone 12 and ribs 80 and 82 are formed in the zones 8 and 12, respectively, the amounts of insulating materials 84 and 86 to be placed in the solar cell module lead line terminal zone 8 and the output cable terminal zone 12 can be reduced. The diode heat sink zone 10 is also filled with the insulating material 88.

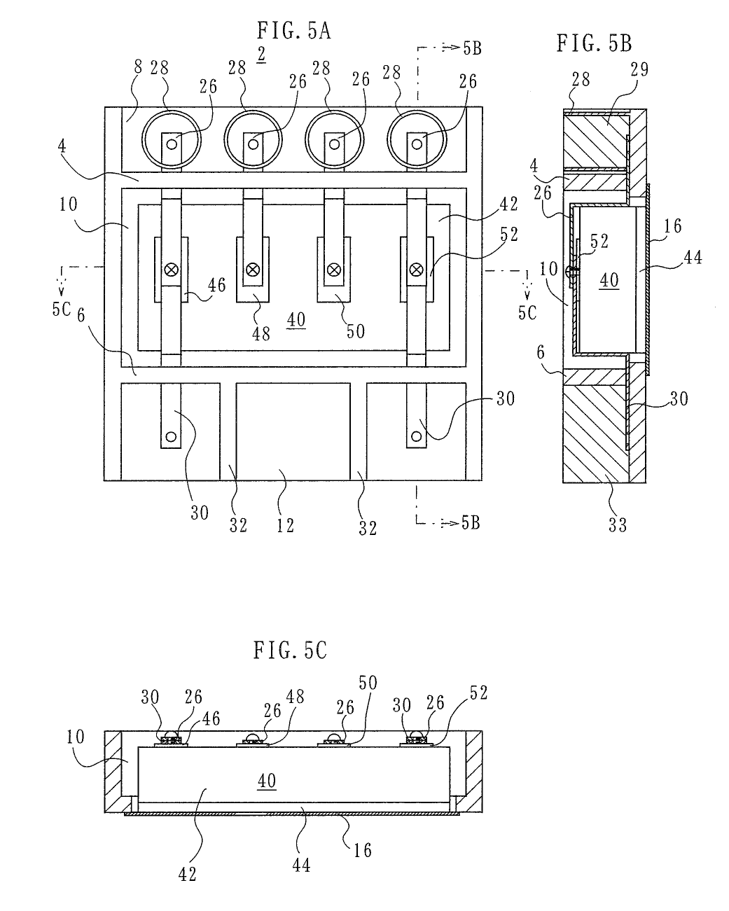

A connector according to a fourth embodiment is shown in FIGS. 5A, 5B and 5C. Different from the first embodiment in which the diode chips 18 are mounted on the heat sinks 14, a diode module 40 is used in the connector according to the fourth embodiment. The arrangement of the remainder of the connector is substantially the same as the connector according to the first embodiment, and, therefore, the same reference numerals are used in FIGS. 5A, 5B and 5C for the same or similar components or functions to those of the connector of the first embodiment. The connector of the fourth embodiment is made in a similar manner to the connector of the first embodiment.

The diode module 40 has a casing 42 of insulating material and includes a plurality, three, for example, of diodes connected in series within the casing 42. A heat sink 44 common to the diodes is disposed at the bottom of the casing 42. Connection terminals 46, 48, 50 and 52 are disposed on the top surface of the casing 42. The cathode of a first one of the diodes is connected to the terminal 46. The anode of the first diode and the cathode of a second one of the diodes are connected to the terminal 48. The anode of the second diode and the cathode of a third one of the diodes are connected to the terminal 50, and the anode of the third diode is connected to the terminal 52.

The respective ones of the solar cell module lead line connection terminals 26 are connected, by means of screws, to the connection terminals 46, 48, 50 and 52, and the respective ones of the output cable connection terminals 30 are connected to the terminals 46 and 52 with screws. The connector of this embodiment is assembled in a similar manner to the connector of the first embodiment. According to this embodiment, since the diodes are within the diode module 40, they can endure temperature and humidity variations, and, if any force is exerted to the connection terminals 26 and 30, the force is not transmitted directly to the diodes since the terminals are not directly connected to the diodes.

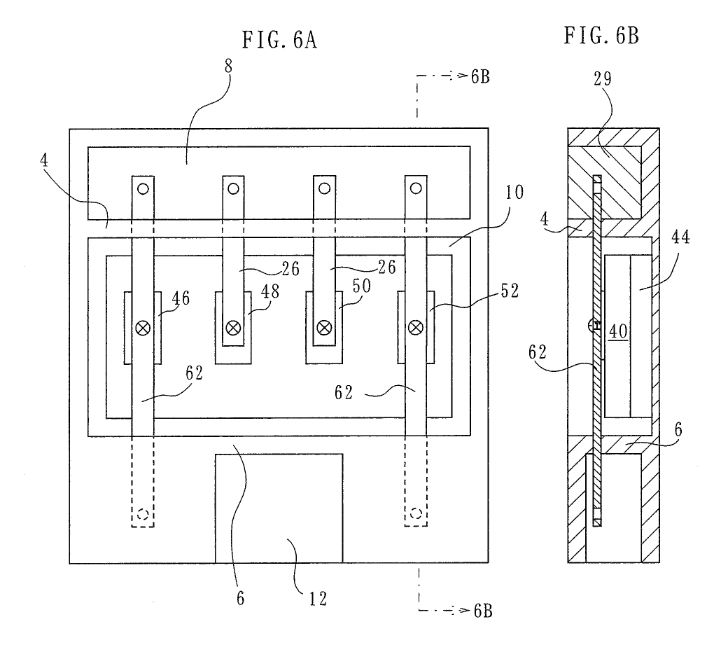

A connector according to a fifth embodiment is shown in FIGS. 6A and 6B. Different from the connector according to the fourth embodiment in which the solar cell module lead line connection terminals 26 and the output cable connection terminals 60 are separate components, according to the fifth embodiment, first terminals, e.g. the terminals 26 dedicated for solar cell module lead lines are connected to the terminals 48 and 50 of the connector, which terminals 48 and 50 are adapted to be connected only to the solar cell module lead lines, while, to the terminals 46 and 52, which are adapted for connection to both the solar cell module lead lines and the output cables, terminals 62 common to the solar cell module lead lines and the output cables are connected. The common terminals 62 extend from the terminal 46 and 52 into both the solar cell module lead line terminal zone 8 and the output cable terminal zone 12. Connectors (not shown) are adapted to be connected to the common terminals 62 in the output cable terminal zone 12. Accordingly, the zone 12 is not filled with an insulating material. The structure of the remainder is similar to the connector according to the fourth embodiment, no further description about it is given, but the same reference numerals are attached to the same or similar components and functions.

The use of the common terminals 62 makes it possible to attach both the solar cell module lead line and output cable connection terminals to the diode module 40 at one time, so that the assemblage of the connector parts becomes easier.

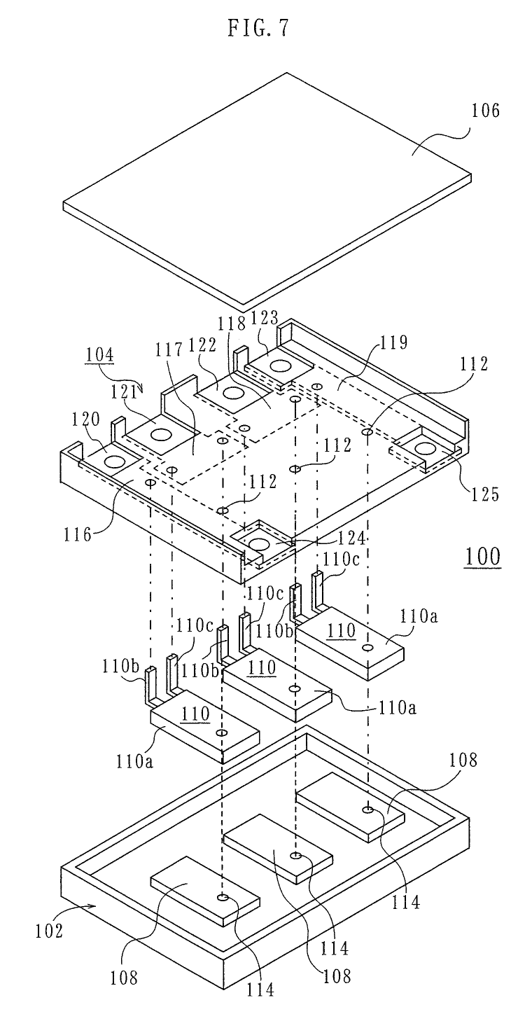

FIG. 7 shows a connector according to a sixth embodiment of the present invention. The connector includes an insulating box 100 having a diode zone in the form of, for example, a mount casing 102, a partition in the form of, for example, an insert casing 104, and a lid 106. The mount casing 102 is a flat, rectangular parallelepiped, having an opening upward, for example, and is formed of insulating material, e.g. epoxy. The insert casing 104 is disposed to close the opening of the mount casing 102, and the lid 106 is disposed on the insert casing 104.

Plural, three, for example, heat sinks 108 are spaced from each other on an upper surface of the bottom of the mount casing 102 along the length direction of the casing 102. As in the connector according to the first embodiment, openings may be formed in the bottom of the mount casing 102, with heat-conductive insulating sheets bonded to close the bottom of the openings. The heat sinks 108 are bonded to the upper surfaces of the respective ones of the heat-conductive insulating sheets. Alternatively, those portions where the heat sinks 108 are to be mounted may be thinned together with portions around them relatively to the remaining portions of the bottom of the mount casing 102.

A molded diode 110 is disposed on each of the heat sinks 108. Each molded diode 110 includes a flat, rectangular parallelepiped insulating case 110a, and cathode and anode electrodes 110b and 110c, respectively, extending upward from one end of the case 110a. A metal sheet (not shown) is disposed on the lower surface of the case 110a, which is disposed on each heat sink 108.

The insert casing 104 is flat and made of an insulating material, e.g. an epoxy resin, and is disposed over the opening of the mount casing 102. Three screw holes 112 are formed in the insert casing 104 at locations corresponding to the molded diodes 110. A screw (not shown) is inserted through each hole 112 and a hole formed in the case 110a of an associated one of the molded diodes 110 and is screwed into a hole 114 in an associated heat sink 108, to thereby secure each molded diode 110 to the associated heat sink 108. Although not shown, an insulating material, e.g. epoxy resin, is placed to embed each molded diode 110 within the mount casing 104.

The cathode and anode electrodes 110b and 110c of each molded diode 110 extend through the insert casing 104. First through fourth lead frames 116, 117, 118 and 119 are disposed at the locations where the cathode and anode electrodes 110b and 110c of the respective molded diodes extend upward through the insert casing 104. The lead frames 116-119 are embedded in the insert casing 104.

The first lead frame 116 is disposed along a first shorter side of the insert casing 104 and extends from a first longer side of the casing 104 to the other, second longer side. At a location intermediate between the first and second opposing longer sides and rather closer to the first longer side, formed is a hole into which the cathode electrode 110b of a first one of the molded diodes 110, which is closest to the first shorter side of the casing 102, is to be inserted. That cathode electrode 110b is connected to the lead frame 116 in the hole by, for example, soldering.

The second lead frame 117 is disposed adjacent to the first lead frame 116 and extends from the first longer side of the insert casing 104 to an intermediate position between the two longer sides of the insert casing 104. The second lead frame 117 is provided with a hole into which the anode electrode 110c of the first molded diode 110 is to be inserted. In this hole, the anode electrode 110c of the first diode 110 is soldered to the second lead frame 117. The second lead frame 117 is also provided with another hole into which the cathode electrode 110b of the second, intermediate molded diode 110 is to be inserted. This cathode electrode 110b and the second lead frame 117 are connected together by soldering in this hole.

The third lead frame 118 is located adjacent to the second lead frame 117 and extends from the first longer side of the insert casing 104 to an intermediate position between the two longer sides of the insert casing 104, as the second lead frame 117. The third lead frame 118 is provided with a hole into which the anode electrode 110c of the second molded diode 110 is to be inserted. In this hole, the anode electrode 110c of the second diode 110 is soldered to the third lead frame 118. The third lead frame 118 is also provided with another hole into which the cathode electrode 110b of the third molded diode 110, which is located adjacent to the second shorter side of the casing 102, is to be inserted. This cathode electrode 110b and the third lead frame 118 are connected together by soldering in this hole.

The fourth lead frame 119 is located adjacent to the third lead frame 118 and adjacent to the second shorter side of the insert casing 104. The fourth lead frame 119 extends from the first longer side to the opposing, second longer side of the insert casing 104. At a location on the fourth lead frame 119 intermediate the first and second longer sides of the insert casing 104, formed is a hole into which the anode electrode 110c of the third molded diode 110 is inserted and soldered to the fourth lead frame 119.

In this manner, the diodes 110 are connected in series by means of the first through fourth lead frames 116-119.

The end portions on the first longer side of the insert casing 104 of the first through fourth lead frames 116-119 are exposed to provide solar cell module lead line connection terminals 120, 121, 122 and 123, respectively. Also, the end portions on the second longer side of the insert casing 104 of the first and fourth lead frames 116 and 119 are exposed to provide output cable connection terminals 124 and 125, respectively. The lid 106 is mounted over the insert casing 104.

Because the lead frames 116-119 are embedded in the insert casing 104 and the solar cell module lead line connection terminals 120-123 and the output cable connection terminals 124 and 125 are formed beforehand, the assemblage into the connector is easier.

What is claimed is:

1. A method of producing a solar cell module panel with bypass diodes, comprising the steps of:
forming an insulating box including a diode zone, a solar cell module lead line connection zone on one side of said diode zone with a first partition disposed between said solar cell module lead line connection zone and said diode zone, and an output cable connection zone on the other side of said diode zone with a second partition disposed between said output cable connection zone and said diode zone;
forming an interim assembly by disposing a series combination of a plurality of diodes in said diode zone, deriving a plurality of lead line connection terminals which respectively extend from opposite ends of said diode series combination and junctions of said serially connected diodes into said solar cell module lead line connection zone, deriving cable connection terminals which extend from the opposite ends of said diode series combination into said output cable connection zone, respectively, and filling said diode zone with an insulating material;
conducting characteristic tests of said interim assembly;
mounting said interim assembly onto a rear surface of a solar cell module panel; and
connecting lead lines of respective solar cell modules of said solar cell module panel to associated ones of said lead line connection terminals, and connecting output cables to said cable connection terminals.
